(19) United States
(12) Patent Application Publication
(10) Pub. No.: US 2011/0109580 A1
(43) Pub. Date: May 12, 2011

(54) Wear-Resistant Touchpads

(76) Inventors: Charles Sellers, Houston, TX (US); Kevin F. Clancy, Spring, TX (US); Philip Ming-Chuan Kao, Taipei (TW)

(21) Appl. No.: 12/991,470

(22) PCT Filed: May 8, 2008
(86) PCT No.: PCT/US2008/062987

§ 371 Date: Jan. 26, 2011

(51) Int. Cl. G06F 3/041; H05K 3/28

(52) U.S. Cl. 345/173; 427/96.2; 178/18.03

(57) ABSTRACT

A touchpad for use with a computing device. The touchpad includes a touch-sensitive element, a cover layer that overlies the touch-sensitive element, and a durable protective coating that has been directly applied to an outer surface of the top layer.

### BACKGROUND

Most notebook computers comprise capacitive touch-sensitive pads, commonly referred to as “touchpads,” that are used to register user inputs. In many cases, the touchpad may be used as a substitute for a separate mouse. Because the touchpad is integrated into the housing of the computer, greater portability and ease of use are enabled.

Because of their convenience, touchpads are normally used by the computer user on a frequent basis. Such use often wears away the matte finish top surface of the touchpad, resulting in the development of a shiny and/or discolored region, typically in the middle of the touchpad. In addition to reducing computer aesthetics, such wear may adversely affect the sensitivity of the touchpad, potentially to the point at which it no longer functions correctly.

Although protective sheeting has been adhered to touchpads in the past in an attempt to reduce touchpad wear, such sheeting can reduce the effectiveness of the touchpads. One reason for that reduction may relate to the layer of adhesive that is used to attach the sheeting to the touchpad. Another reason may relate to the thickness of the sheeting.

### BRIEF DESCRIPTION OF THE DRAWINGS

The disclosed touchpads can be better understood with reference to the following drawings. The components in the drawings are not necessarily to scale.

FIG. 1 is a perspective view of an embodiment of a computing device that incorporates a touchpad comprising a durable protective coating.

FIG. 2 is a schematic diagram illustrating a first example apparatus for applying a durable protective coating.

FIG. 3 is a schematic diagram illustrating a second example apparatus for applying a durable protective coating.

FIG. 4 is a schematic diagram illustrating a third example apparatus for applying a durable protective coating.

FIG. 5 is a schematic side view of a touchpad comprising a durable protective coating.

FIG. 6 is a flow chart of an embodiment of a method for producing a wear-resistant touchpad.

### DETAILED DESCRIPTION

As described above, touchpads are susceptible to wear that can negatively affect the appearance of the computer as well as the functionality of the touchpad. Although protective sheeting can be adhered to a touchpad to reduce such wear, such sheeting may adversely affect the sensitivity of the touchpad. As described in the following, however, desirable wear resistance can be attained without the use of protective sheeting when a durable protective coating is used. In some embodiments, the durable protective coating is roller coated onto the surface of sheet material that is incorporated into the touchpad.

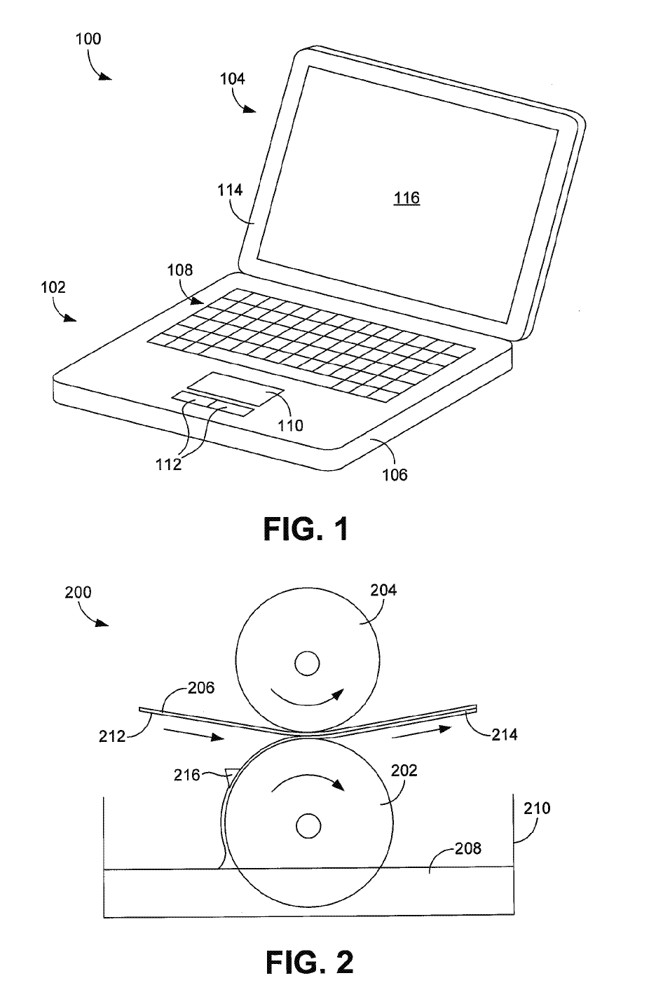

Referring now to the figures, in which like numerals identify corresponding elements, illustrated in FIG. 1 is an embodiment of a computing device 100 configured as a notebook or “laptop” computer. The computing device 100 generally comprises a base portion 102 and a display portion 104. The base portion 102 comprises a housing 106 that contains various internal components of the computing device 100, such as one or more processors, memory, a hard drive, and the like. Also comprised by the base portion 102 is a user interface including a keyboard 108, a capacitive touchpad 110, and selection buttons 112. The display portion 104 also comprises a housing 114 that surrounds a display 116, such as a liquid crystal display (LCD).

The touchpad 110 comprises a durable protective coating (not visible in FIG. 1) that forms an outer surface of the touchpad. In some embodiments, the durable protective coating is applied in liquid form to a polymeric sheet material used to construct the touchpad.

FIG. 2 illustrates a first example roller coating apparatus 200. In the present disclosure, the terms “roll coat,” “roller coat,” “roll coating,” and “roller coating” are used to refer to a process by which a liquid material is applied to a sheet of material using an application roller that directly applies the liquid to a surface of the sheet. As indicated in FIG. 2, the apparatus 200 includes an application roller 202 and a pressure roller 204 between which a continuous sheet 206 of polymeric material passes. In some embodiments, the sheet 206 is formed of a polyester material. The application roller 202 is partially immersed in a bath of ultraviolet (UV) curable liquid polymer 208 (e.g., UV-curable resin) that, once cured, will form a durable protective coating. The liquid polymer 208 is contained in a tank 210 in which the application roller 208 has been positioned.

During the coating process, the rollers 202, 204 rotate in opposite directions and the sheet 206 is drawn between a nip formed between the rollers. Because the application roller 202 is partially immersed in the liquid polymer 208, rotation of that roller draws the liquid polymer out of the tank 210 and into contact with a surface 212 of the sheet 206 that faces the application roller. In some embodiments, the surface of the application roller 202 comprises engraved depressions that assist in the delivery of liquid polymer to the sheet 206.

As is further indicated in FIG. 2, application of the liquid polymer 208 in the manner described above results in a layer 214 of liquid polymer being formed on the surface 212. In some embodiments, the apparatus 200 includes a blade 216 that removes excess liquid polymer 208 from the surface of the application roller 202 and therefore controls the thickness of the layer 214 formed on the sheet 206. Once the layer 214 has been formed, it can be cured in place on the sheet 206. By way of example, the layer 214 is cured in a UV oven in which the layer is exposed to UV radiation that hardens the layer. After curing, the sheet 206 can be cut into multiple portions (e.g., rectangles) for use in constructing multiple touchpads.

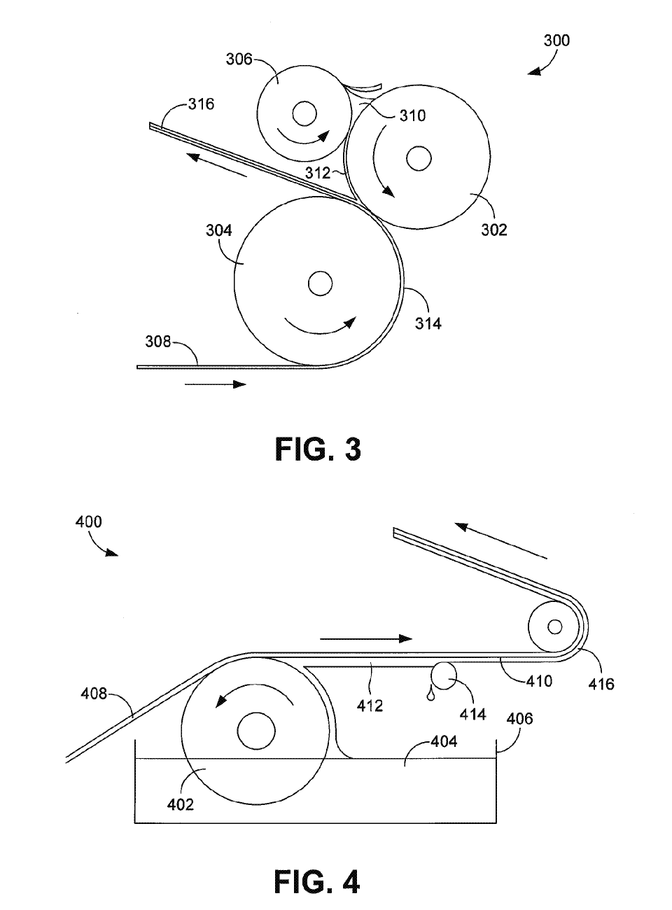

FIG. 3 illustrates a second example roller coating apparatus 300. As indicated in FIG. 3, the apparatus 300 includes an application roller 302, a support roller 304, and a metering roller 306. During the coating process, the support roller 304 rotates in a counterclockwise direction (in the orientation of the figure) to draw a continuous sheet 308 of polymeric material past the application roller 302, which rotates in the same direction as the support roller.

Supported by the application roller 302 and the metering roller 306 is a quantity of UV-curable polymer solution 310. A thin layer 312 of UV-curable liquid polymer, having a thickness generally equal to the size of a gap formed between the application roller 302 and the metering roller 306, forms on the surface of the application roller, which carries the liquid polymer to a surface 314 of the sheet 308. This results in a layer 316 of liquid polymer being deposited on the surface 314 of the sheet 308. As described in relation to FIG. 2, the layer 316 can be cured in place on the sheet 308 and the sheet can then be cut into multiple portions for use in constructing multiple touchpads.

FIG. 4 illustrates a third example roller coating apparatus 400. As indicated in FIG. 4, the apparatus 400 includes an application roller 402 that, like the application roller 202 from FIG. 2, is partially immersed in a bath of UV-curable liquid polymer 404 contained within a tank 406. During the coating process, the application roller 402 rotates in a direction opposite to a direction of travel of a continuous sheet 408 of polymeric material that is to be coated. Because the application roller 402 is partially immersed in the liquid polymer 404, rotation of that roller draws liquid polymer 404 out of the tank 406 and into contact with a surface 410 of the sheet 408. The liquid polymer 404 is therefore deposited on the surface 410 of the sheet 408 to form a layer 412. As indicated in FIG. 4, that layer 412 can be reduced in thickness using a Meyer bar 414 such that a layer 416 of a desired thickness is obtained. Again, the layer 416 can be cured in place on the sheet 408, and the sheet can then be cut into multiple portions for use in constructing multiple touchpads.

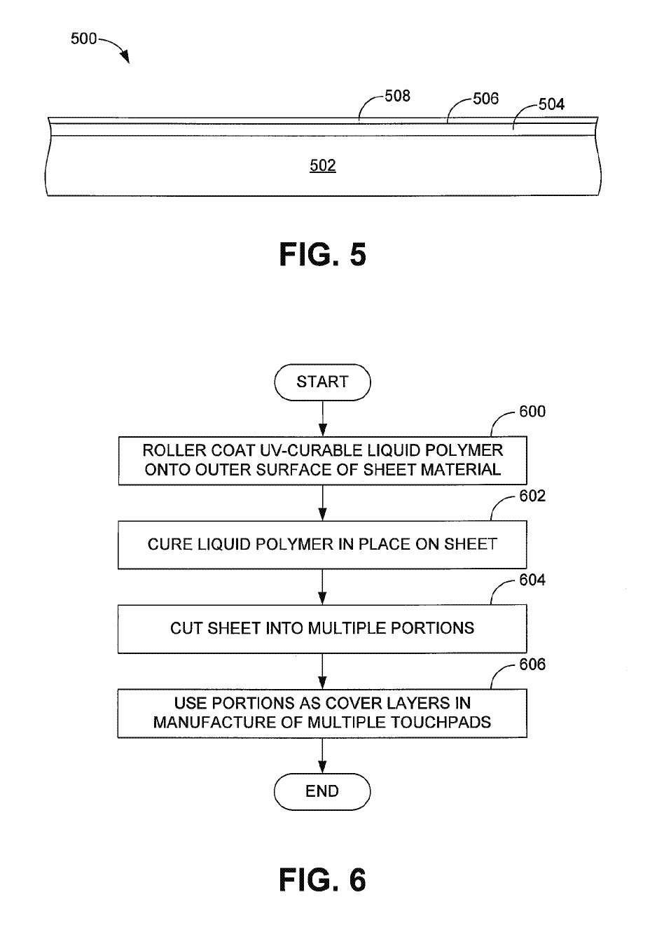

Schematically illustrated in FIG. 5 is a touchpad 500 that includes a durable protective coating. As indicated in FIG. 5, the touchpad 500 includes a touch-sensitive element (e.g., capacitive sensor) 502 and a cover layer 504 that overlies the element. The cover layer 504 comprises a portion of the polymeric sheet material to which the liquid polymer was applied, as described in the foregoing. Therefore, the cover layer 504 can comprise a polyester layer or film. Regardless, the cover layer 504 comprises an outer surface 506 on which has been formed an outer layer 508 that has been cured to form a durable protective coating. By way of example, the outer layer 508 is approximately 5 to 25 microns (μm) thick.

Because the durable protective layer (i.e., outer layer 508) is directly applied onto the outer surface 506 of the cover lay 504, there is no adhesive layer to alter the dielectric properties of the touchpad. Moreover, because the durable protective layer is so thin, the layer has a minimal effect on the dielectric properties of the touchpad 500 and, therefore, does not significantly affect the operation or use of the touchpad. Despite the thinness of the durable protective layer, significant wear-resistance is achieved.

FIG. 6 is a flow chart that describes actions of an embodiment of a method for producing a touchpad consistent with the above disclosure. Beginning with block 800, a UV-curable liquid polymer is roller coated onto an outer surface of a sheet of material, such as a sheet of polyester. Next, the liquid polymer is cured in place on the sheet, as indicated in block 602. The sheet is then cut into multiple portions, as indicated in block 604, and the portions are used as cover layers in the manufacture of multiple touchpads, as indicated in block 606.

1. A touchpad for use with a computing device, the touchpad comprising:
a touch-sensitive element;
a cover layer that overlies the touch-sensitive element; and
a durable protective coating that has been directly applied to an outer surface of the cover layer.

2. The touchpad of claim 1, wherein the durable protective coating has been roller coated onto the cover layer.

3. The touchpad of claim 1, wherein the cover layer is composed of a polymeric material.

4. The touchpad of claim 1, wherein the durable protective coating is an ultraviolet-cured coating.

5. The touchpad of claim 1, wherein the durable protective coating is approximately 5 to 25 microns thick.

6. A touchpad for use with a computing device, the touchpad comprising:
a capacitive sensor;
a cover layer that overlies the sensor, the cover layer including an outer surface; and
an ultraviolet-cured durable protective coating that has been roller coated onto the outer surface of the cover layer.

7. The touchpad of claim 6, wherein the durable protective coating is approximately 5 to 25 microns thick.

8. A computing device comprising:
a base portion;
a display portion pivotally connected to the base portion; and
a user interface provided on the base portion, the user interface including a touchpad having a cover layer and a durable protective coating that has been directly applied to the cover layer.

9. The computing device of claim 8, wherein the cover layer of the touchpad is composed of a polymeric material.

10. The computing device of claim 8, wherein the cover layer of the touchpad is composed of a polyester material.

11. The computing device of claim 8, wherein the durable protective coating is an ultraviolet-cured coating.

12. The computing device of claim 8, wherein the durable protective coating is approximately 5 to 25 microns thick.

13. A method for producing a touchpad, the method comprising:
applying liquid polymer to an outer surface of a sheet of material;
curing the liquid polymer in place on the sheet;
cutting out a portion of sheet; and
using the portion as a cover layer of a touchpad.

14. The method of claim 13, wherein applying liquid polymer comprises applying an ultraviolet-curable liquid polymer to the outer surface of the sheet.

15. The method of claim 13, wherein applying liquid polymer comprises roller coating the liquid polymer onto the outer surface of the sheet.

16. The method of claim 15, wherein curing the liquid polymer comprises exposing the ultraviolet-curable polymer liquid to ultraviolet radiation.
